(19) United States
(12) Patent Application Publication
(10) Pub. No.: US 2009/0051033 A1
(43) Pub. Date: Feb. 26, 2009

(54) RELIABILITY IMPROVEMENT OF METAL-INTERCONNECT STRUCTURE BY CAPPING SPACERS

(75) Inventors: Laurent Gosset, Eindhoven (NL); Vincent Arnal, Grenoble (FR); Mohamed Aimadeddine, Grenoble (FR); Joaquin Torres, Saint Martin le Vinoux (FR)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 12/159,652

(22) PCT Filed: Dec. 19, 2006
(86) PCT No.: PCT/EP06/69911

§ 371 Date: Jun. 30, 2008

(30) Foreign Application Priority Data
Dec. 29, 2005 (EP) 05301118.5

(51) Int. Cl. H01L 21/768; H01L 23/522

(52) U.S. Cl. 257/751; 438/627; 257/E23.142; 257/E21.584

(57) ABSTRACT

The present invention relates to a metal-interconnect structure for electrically connecting integrated-circuit elements in an integrated-circuit device. It solves several problems of operational reliability in damascene interconnect structures, due to corner effects and structural defects present at top edges of interconnect lines fabricated according to prior-art processing technologies. In alternative configurations of the metal interconnect structure, capping spacers (334) are arranged abutting and covering outer top edges (316c) of interconnect lines (304) or lateral barrier liners (316), respectively. The interconnect structure of the invention eliminates the negative influence of these critical regions in the metal-interconnect structure on the operational reliability of an integrated-circuit device.

The present invention relates to a metal-interconnect structure for electrically connecting integrated-circuit elements. It further relates to an integrated circuit device with a substrate comprising a plurality of integrated-circuit elements, and with a metal-interconnect structure on the substrate for interconnecting integrated-circuit elements. The invention also relates to a method for fabricating an integrated-circuit device.

Current technologies for fabricating ultra-large scale integrated-circuit devices employ copper interconnects. Copper has replaced aluminum as the interconnect material due to its lower specific resistance and improved electromigration (EM) characteristics.

However, the use of copper for interconnect lines has several disadvantages that must be taken care of in the fabrication of integrated-circuit devices. Copper diffuses into surrounding silicon or silicon dioxide layers already at very low temperatures. Copper is oxidized and corroded under the influence of materials present in standard processing, such as oxygen or hydrofluoric acid (HF). In order to prevent outdiffusion of copper from the interconnect lines and a corrosion of the copper interconnect lines, the interconnect lines are typically surrounded by barrier liners.

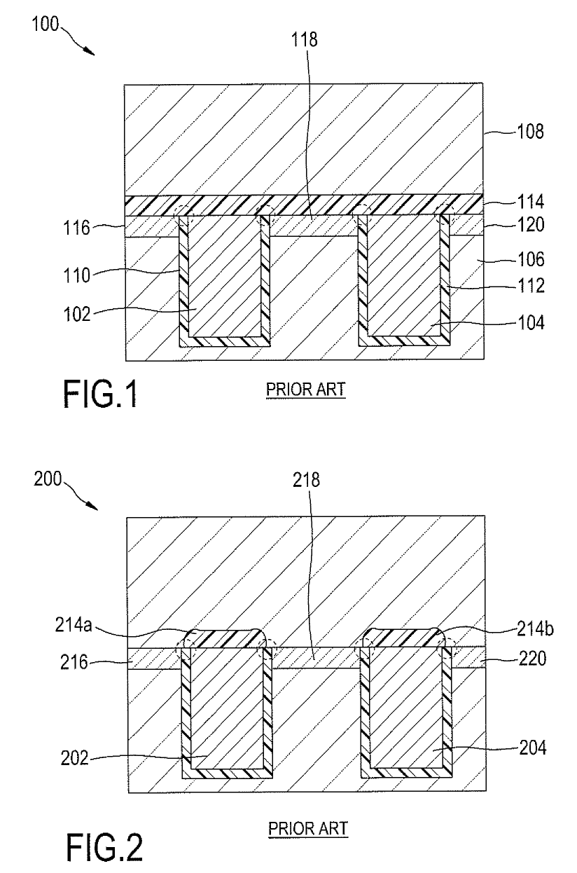

Copper interconnect structures are fabricated by employing a damascene process or a dual damascene process, both of which are well known in the art. It turns out that integrated-circuit device fabricated by such known processes for copper interconnect structures exhibit a reduced reliability. This problem will be elucidated in the following with reference to FIGS. 1 and 2.

FIGS. 1 and 2 show two alternative interconnect structures according to the prior art. An interconnect structure 100 shown in FIG. 1 comprises copper interconnect lines 102 and 104, which are separated from surrounding dielectric material layers 106 and 108 by barrier liners 110 to 114. Barrier liner 110 confines the interconnect line 102 laterally and on its bottom face. Similarly, barrier liner 112 confines interconnect line 104 on its lateral and bottom faces. A top barrier liner 114, which is made from a dielectric material and can in the present interconnect architecture also be referred to as a dielectric capping layer 114, is deposited on top of the interconnect lines 102 and 104, and on top of residual hard-mask sections 116, 118, and 120. A hard-mask material, which is typically employed, is undoped silicate glass (USG).

An alternative interconnect structure 200 is shown in FIG. 2. It resembles that of FIG. 1 with the exception that self-aligned top barrier liners 214A and 214B are arranged on each interconnect line 202 and 204 instead of an uninterrupted dielectric capping layer 114.

A disadvantageous effect regarding operating reliability is formed by a concentration of the electrical field on top edges of the interconnect lines during operation. Such edges are marked for clarity by open circles in FIGS. 1 and 2. These edges are known to cause operational breakdown or EM failures due to electrical-field concentration.

Another issue related to these edges is a local penetration of interconnect metal out off the interconnect line and local penetration of corroding substances into the interconnect line during processing. Both effects decrease operational reliability due to current leakage and thus increase the risk of operational breakdown.

It is therefore preferred to provide an integrated-circuit device that has an improved operational reliability. It is a further object of the present invention to provide a method for fabricating an integrated-circuit device that improves the operational reliability of the device.

According to a first aspect of the invention, a metal-interconnect structure on a substrate is provided, comprising a plurality of metal-interconnect lines on one or more interconnect levels, the metal-interconnect lines comprising copper and being separated laterally from an inter-metal dielectric by a respective lateral barrier liner, and being separated on their top face from the inter-metal dielectric by a top barrier liner, the lateral and top barrier liners each forming a barrier against a penetration of copper out off a respective metal-interconnect line and against a penetration of a material suitable for corroding copper into a respective metal-interconnect line.

The first aspect of the invention encompasses three alternative configurations of a metal-interconnect structure, which are herein generally referred to as the first, second and third alternative configuration, or as alternatives a), b) and c), respectively:

a)

In a first alternative, the top barrier liner of a respective interconnect line extends only on the metal of the interconnect line. Capping spacers are arranged abutting and covering respective outer top edges of the interconnect line and outer bottom edges of the top barrier layer.

b)

In a second alternative, the top barrier liner of an interconnect line extends from an outer edge of a lateral barrier liner on one lateral side of a respective interconnect line to an outer edge of a lateral barrier liner on an opposite lateral side of the respective interconnect line. Capping spacers are arranged abutting and covering a top section of a respective lateral outer face of the lateral barrier liner, and extend beyond the outer top edge of the lateral barrier liner along a respective lateral outer face of the respective top barrier liner.

c)

In a third alternative, the top barrier liner of an interconnect line laterally continues between neighboring interconnect lines. Capping spacers are arranged abutting and covering a top section of a respective lateral outer face of the lateral barrier liner and extending to an outer top edge of the lateral barrier liner. The capping spacers of this alternative are covered on their top faces by the top barrier liner.

A second aspect of the invention is formed by an integrated-circuit device with a substrate comprising a plurality of integrated-circuit elements, and with a metal-interconnect structure according to the first aspect of the invention on the substrate. The following description relates to both, the first and second aspects of the invention. It is obvious that embodiments and advantages of the integrated-circuit device of the second aspect of the invention correspond to those of the metal-interconnect structure of the first aspect of the invention.

The terms “outer” and “inner” are used herein to describe lateral orientations of faces, edges, etc. in relation to a respective allocated interconnect line. “Outer” edges of a lateral barrier liner thus are those edges of the lateral barrier liner, which face away from the interconnect line, to which the barrier liner is allocated. “Inner” edges of the lateral barrier liner are those edges of the lateral barrier liner, which face towards that interconnect line. The attribute “top” in connection with an edge, face or side of structural elements generally refers to an edge, face or side that faces away from a substrate, on which the interconnect structure is arranged. A “top” face of a lateral barrier liner thus faces away from the substrate. Correspondingly, a “top” barrier liner is arranged on a top face of an interconnect line. “Top” lateral sections of a lateral barrier liner are lateral sections, which are close to the top face of the lateral barrier liner.

The term “penetration” is used to include different effects, by which transporting material across a barrier is enabled, such as diffusion, or transport through structural defects such as dislocation networks, cracks or leaks, etc.

Note that the term “interconnect line” is used herein to include any metal segment of the metal-interconnect structure that serves to transport electrical or electromagnetic signals, for instance between integrated-circuit elements of the integrated-circuit device, or between an integrated-circuit element and an electrical interface with an external device. In particular, the term “interconnect line” includes metal segments of the interconnect structure, which do not have the appearance of a line in the geometrical sense of the word.

The metal-interconnect structure of the invention, herein also referred to in short as interconnect structure, eliminates the negative influence of the above-identified critical regions in the metal-interconnect structure on the operational reliability of an integrated-circuit device.

In each of the three alternative configurations a), b) and c), the capping spacers cover a respective critical edge of the interconnect line and/or the lateral barrier liner, thereby effectively reducing interline current leakage. A reliability enhancement is thus achieved by an improved robustness, thus increasing the dielectric lifetime. Electric-field concentrations can be remarkably reduced.

The three alternative configurations of the metal-interconnect structure of the invention correspond to an alternative use of a top barrier liner in the form of a capping layer or of a self-aligned top barrier liner, as already set out in the alternative prior-art structures of FIGS. 1 and 2. A further differentiation is necessary with regard to the self-aligned top barrier liner, since this can either cover the lateral barrier liner or not. Note, however, that this differentiation is not bound to the use of a particular processing method. The structure of the invention is disclosed and claimed herein independent from a particular fabrication method.

In the first alternative configuration, the top barrier liner of a respective interconnect line extends only on the metal of the interconnect line. It does not cover the respective lateral barrier liner on either side. For the present purpose of defining the lateral extension of the top barrier liner, the lateral barrier liner is not considered a part of the interconnect line, even for the case where the lateral barrier liner itself is a metallic layer (e.g., TiN) and thus able to contribute to current transport.

This configuration can for instance be achieved with a self-aligned deposition process, where deposition of the top barrier liner material selectively takes place only on the material of the interconnect line. Other ways of obtaining this configuration are, of course, possible. For instance, the top barrier liner could be deposited with a larger lateral extension and then laterally structured.

When using a self-aligned top barrier liner that only covers the metal interconnect line and not the lateral barrier liner in the prior-art structure of FIG. 2, the inner top edges form “triple points”, in which the metal interconnect line, the lateral barrier liner and the hard mask abut each other. This triple point exhibits a particular affinity to causing operating failures. The capping of this triple point according to the present embodiment strongly increases the reliability of an integrated-circuit device.

Different lateral extensions of the capping spacers can be used for this configuration. In one embodiment, a bottom face of a respective capping spacer laterally extends only on an abutting top face of the respective lateral barrier liner. In an alternative embodiment, the bottom face of a respective capping spacer extends on an abutting top face of the respective lateral barrier liner and into the inter-metal dielectric, preferably also covering an outer top edge of the lateral barrier liner.

In the second alternative configuration, the top barrier liner of an interconnect line extends from an outer edge of a lateral barrier liner on one lateral side of a respective interconnect line to an outer edge of a lateral barrier liner on an opposite lateral side of the respective interconnect line. The top barrier liner thus also covers the lateral barrier liner, without, however, extending beyond it.

This configuration can also be achieved with a self-aligned deposition process, where deposition of the top barrier liner material selectively takes place only on the material of the interconnect line and of the lateral barrier liner. The top barrier liner could be first deposited with a larger lateral extension and then laterally structured.

In this second alternative configuration, the capping spacers avoid the above-described reliability problems, which would in the absence of the capping spacers be caused at the outer top edges of the lateral barrier liners and outer bottom edges of the top barrier liner.

In the third alternative configuration, the top barrier liner of an interconnect line laterally continues between neighboring interconnect lines. That is, it extends on the interconnect lines, the lateral barrier liners, and continues into the surface between neighboring interconnect lines. The top barrier liner of this configuration can form a continuous layer that covers the whole surface between neighboring interconnect line, or only a part of it.

In this third alternative configuration, the capping spacers avoid the above-described reliability problems, which would in the absence of the capping spacers be caused at the outer top edges of the lateral barrier liners.

The capping spacers of this third alternative cover a top section of a respective lateral outer face of the lateral barrier liner and extend to the outer top edge of the respective lateral barrier liner. Note that the term “top section” used in connection with a respective lateral outer face of the lateral barrier liner means that not only the outer top edge of the lateral barrier liner is covered by the capping spacer, but also an adjacent part of the outer face. The minimum extension of the capping spacer in a direction from the top edge to the substrate, that is, the extension of the “top section” in this direction, is determined by the purpose of avoiding the above-described reliability problems. Beyond that it can be chosen according to processing needs. As will be seen further below, the extension of the capping spacers along lateral outer faces of the lateral barrier liners is in one embodiment defined by a thickness of a hard mask, which is removed from the top lateral sections of the lateral barrier liners prior to deposition of the capping spacers.

The advantage of this third alternative configuration of the metal-interconnect structure of the invention is best explained in view of the prior-art metal-interconnect structures shown in FIGS. 1 and 2. Both structures suffer from the fact that the hard mask sections 116 to 120 or 216 to 220, respectively, are damaged during the damascene or dual damascene process, particularly during the step of chemical mechanical polishing (CMP), which serves to remove residual copper from regions outside the interconnect lines 102, 104, and 202, 204, respectively. Damages in the residual hard-mask sections increase an interline current leakage due to surface defects and due to a larger concentration of impurities generated during the CMP step. Interline current leakage refers to undesired electrical currents between interconnect lines. Further, the interline capacitance is increased due to a high permittivity of the damaged hard-mask sections. Damages in the residual hard-mask sections may finally reduce adhesion between the dielectric capping layer 114 and the residual hard-mask sections 116 to 120.

Therefore, by providing capping spacers also in the outer top lateral sections of the lateral barrier liners, an efficient shielding against interline leakage is provided, and the capacitance is decreased.

In summary, the three alternative configurations share the common effect of avoiding reliability problems at respective outer top edge regions of the interconnect structures, which are caused by electrical-field concentration and material penetration.

Lateral spacers arranged abutting a top lateral section of metal interconnect lines are known from U.S. Pat. No. 6,207,556. The spacers serve as an etch stop layer that avoids an etching of the dielectric layer in the immediate lateral neighborhood of an interconnect line when forming an interconnect line on top in the next interconnect level.

The interconnect architecture of U.S. Pat. No. 6,207,556 B1 is based on a fabrication technology that involves the deposition and subsequent masked etching of a full metal layer in order to form interconnect lines according to a desired structure. This technology is typical for aluminum-based interconnect architectures. No barrier liners are used for the metal interconnect lines in U.S. Pat. No. 6,207,556 B1. Employing copper in the metal interconnect lines interconnect structure of U.S. Pat. No. 6,207,556 B1 thus would lead to strong reliability problems due to an outdiffusion of copper into the inter-metal dielectric, and due to a corrosion of the copper of the interconnect lines. The structure disclosed in U.S. Pat. No. 6,207,556, is therefore fundamentally different from that of the integrated-circuit device of the present invention.

In the following, preferred embodiments of the integrated-circuit device of the invention will be described. The embodiments can be combined with each other, unless explicitly described as alternatives.

In a first embodiment of the third alternative configuration of the metal-interconnect structure of the invention, first top-barrier-liner sections, which extend between two laterally neighboring interconnect lines on the same interconnect level, contain second top-barrier-liner sections, which are arranged closer to the substrate than the top faces of the interconnect lines. A respective capping spacer is laterally arranged between the lateral barrier liner of a respective interconnect line and a respective second top barrier liner section, and covered by a bending portion of the first top barrier liner section, which extends between the top face of the respective interconnect line and the respective second top-barrier-liner section.

This embodiment preferably makes use of a continuous capping layer, preferably a dielectric capping layer. This embodiment implies the total or partial removal of a hard mask layer between neighboring interconnect lines during the fabrication. This embodiment has a further increased reliability, as will be explained in more detail in the context of a preferred embodiment of the method of the invention.

Different material compositions of the capping segments are possible. Preferably the material of the capping spacers is suitable for forming a barrier against a penetration of copper out off a respective interconnect line and against a penetration of a material suitable for corroding copper into a respective interconnect line. In particular, like the lateral and top barrier liners the capping segment material should form a barrier against a diffusion of oxygen into the interconnect line. This enhances the sealing effect of the top and lateral barrier liners.

In one such embodiment, which is preferably used in combination with self-aligned top barrier liners the capping spacers either comprise or consist of a metallic material that is suitable for forming such a barrier. TiN, TaN and Ta form (non-limiting) examples of suitable metals.

Alternatively, the capping spacers either comprise or consist of an electrically insulating material. Silicon nitride, silicon carbide, or a mixture of silicon carbide and silicon nitride form (non-limiting) examples for this case.

Preferably, the capping spacers are made from a dielectric material that has a higher dielectric permittivity than the inter-metal dielectric. Since the electrical field is inversely proportional to the dielectric permittivity, increasing the dielectric permittivity allows lowering the electrical field, thus reducing the corner effect. Preferred dielectric coefficients k are larger than 7 or at least higher than the dielectric coefficient of the top barrier liner. In this way, the electric field strength at the corners is decreased and therefore, reliability and lifetime of the interconnect structure are improved. Apart from the actual structure of the capping spacers, adding only this feature to the commonly known dual damascene process flow would yield a novel and inventive structure. The major difference with U.S. Pat. No. 6,207,556 is, besides the differences already referenced, that a person skilled in the art would not use any further materials that have a higher dielectric constant than the dielectric between the interconnect. This is because this would only enhance cross-talk, decreasing the maximum frequency to be used by the circuit.

According to a third aspect of the invention, a method for fabricating an integrated-circuit device is provided. The method comprises the steps of
providing a substrate comprising a plurality of integrated-circuit elements;
depositing a dielectric layer;
fabricating a plurality of interconnect lines in the dielectric layer.

The step of fabricating the interconnect lines comprises
depositing a hard mask on the dielectric layer and opening the hard mask at desired positions of the interconnect lines;
forming a recess in the dielectric layer for each interconnect line through the openings of the hard mask;
depositing a lateral barrier liner in each recess;
depositing a metal comprising copper;
removing the deposited metal from outside the recesses;
depositing a top barrier liner on each interconnect line.

The method of the third aspect of the invention encompasses three processing alternatives for fabricating a metal-interconnect structure, which correspond to the three configurations of the metal-interconnect structure of the first aspect of the invention and will correspondingly be referred to as the first, second and third alternative configuration, or as alternatives a), b) and c), respectively:

a)

In a first alternative, the top barrier liner of a respective interconnect line is deposited only on the metal of the interconnect line, and the capping spacers are arranged abutting and covering respective outer top edges of the interconnect line and outer bottom edges of the top barrier layer.

b)

In a second alternative, the top barrier liner of an interconnect line is deposited with a lateral extension from an outer edge of a lateral barrier liner on one lateral side of a respective interconnect line to an outer edge of a lateral barrier liner on an opposite lateral side of the respective interconnect line, and capping spacers are arranged abutting and covering a top section of a respective lateral outer face of the lateral barrier liner, and extending beyond the outer top edge of the lateral barrier liner along a respective lateral outer face of the respective top barrier liner.

c)

In a third alternative, before the step of depositing the top barrier liner, capping spacers are arranged abutting and covering a top section of a respective lateral outer face of the lateral barrier liner and extending to an outer top edge of the lateral barrier liner, and wherein the top barrier liner of an interconnect line is deposited laterally continuing between neighboring interconnect lines, thus covering the top faces of the capping spacers with the top barrier liner.

The method of the invention achieves the advantages, which were explained above in the context of the interconnect structure of the first aspect of the invention. It allows improving the operating reliability of interconnect structures fabricated according to a damascene or dual damascene process.

In the following, preferred embodiments of the method of the invention will be described. Again, the embodiments can be combined with each other unless explicitly described as alternative embodiments.

A preferred embodiment comprises a step of (totally) removing the hard mask, which step is performed in the first and second alternatives before the step of depositing the top barrier liner, and in the third alternative before the step of depositing the capping spacers.

Hard mask sections that remain after the step of removing the deposited metal from outside the recesses. This removing step, which is typically performed by CMP, generally involves the creation of a large number of defects in on the hard-mask surface. Also, impurities are introduced into the residual hard-mask sections. This increases the interline capacitance due to the resulting high permittivity of the hard mask residuals. Also, in the third alternative of the fabrication method, the adhesion between the top barrier liner and the hard mask is reduced. Therefore, a removal of these hard mask sections also removes the defects and risks generated by the previous processing, and thus further increases device reliability. This embodiment is applicable for the three alternative fabrication methods of the invention.

It would in principle also be possible to remove only parts of the hard mask in order to achieve an improvement over the prior-art structures. However, this improvement would not have the full advantage of completely removing the hard mask, since some of the problems associated with the hard masks would remain with the remaining portions of the hard mask.

In one embodiment, the step of fabricating capping spacer comprises a step of depositing a capping-spacer layer and a (preferably mask-less) etching step applied to the capping-spacer layers so as to form the capping spacers. By this processing, capping spacers can be formed with a desired lateral extension. The lateral extension of the capping spacers should be sufficient to provide the desired effects of reducing interline leakage and, preferably, avoiding penetration to and from the interconnect line, as explained before in the context of several preferred embodiments. An adjustment of the lateral extension of the capping spacers can be used as in U.S. Pat. No. 6,207,556 B1 to provide an etch stop in the fabrication of the next interconnect level and avoid lateral misalignment issues.

A further embodiment comprises a step of fabricating a top barrier liner that covers a top face of a respective interconnect line. The step can be performed either before or after the step of fabricating the capping spacer. In a first processing alternative comprised by this embodiment, the top barrier liner is deposited on the whole substrate surface after the step of fabricating capping spacers. In a second, alternative processing alternative of this embodiment, the top barrier liner is deposited self-aligned with the interconnect lines, and the step of fabricating capping segment is performed after the deposition of the top barrier liner. In the latter embodiment, the deposition of the top barrier liner helps to selectively remove the hard mask in a mask-less etching step, thus making the processing particularly simple

In the following, further embodiments of the different aspects of the invention will be explained with reference to the figures.

FIGS. 1 and 2 show two alternative interconnect structures according to the prior art.

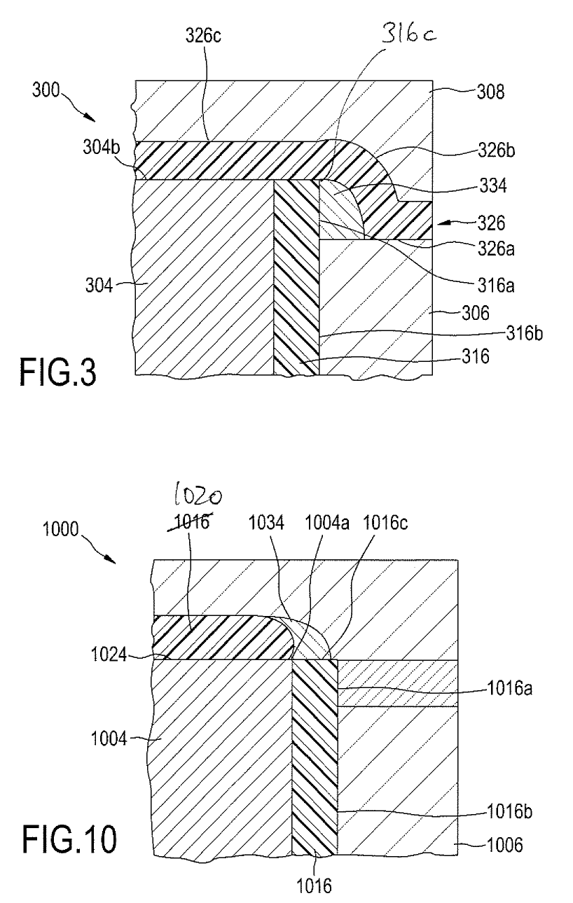

FIG. 3 shows a schematic enlarged cross-sectional view of a portion of an interconnect structure that includes a top lateral section of an interconnect line and an adjacent lateral barrier liner, according to a first embodiment of a metal-interconnect structure.

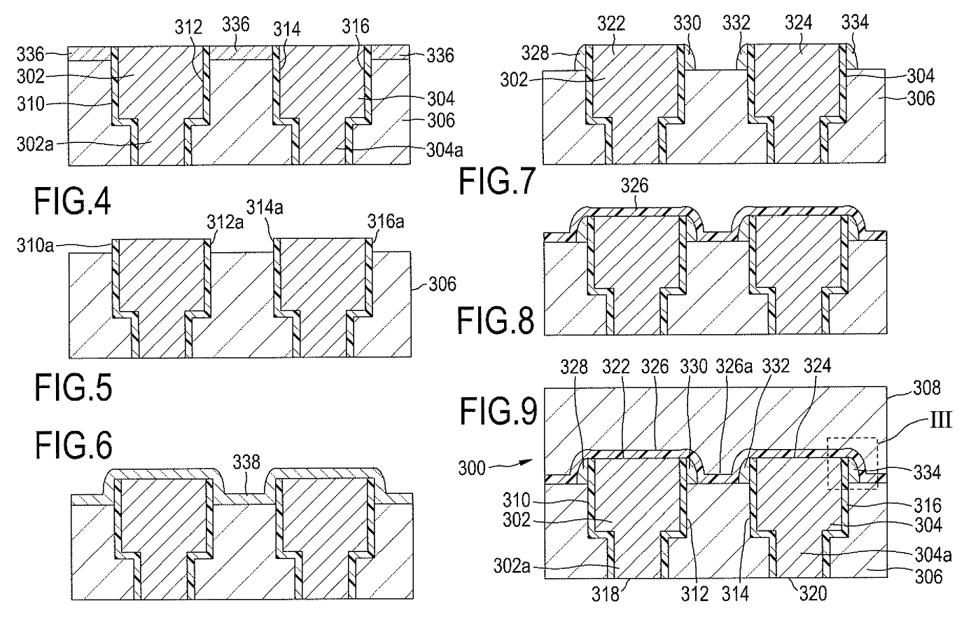

FIGS. 4 to 9 show different steps during the processing of the interconnect structure of FIG. 3 according to an embodiment of the method of the invention.

FIG. 10 shows a schematic enlarged cross-sectional view of a portion of an interconnect structure that includes a top lateral section of an interconnect line and an adjacent lateral barrier liner, according to a second embodiment of a metal-interconnect structure.

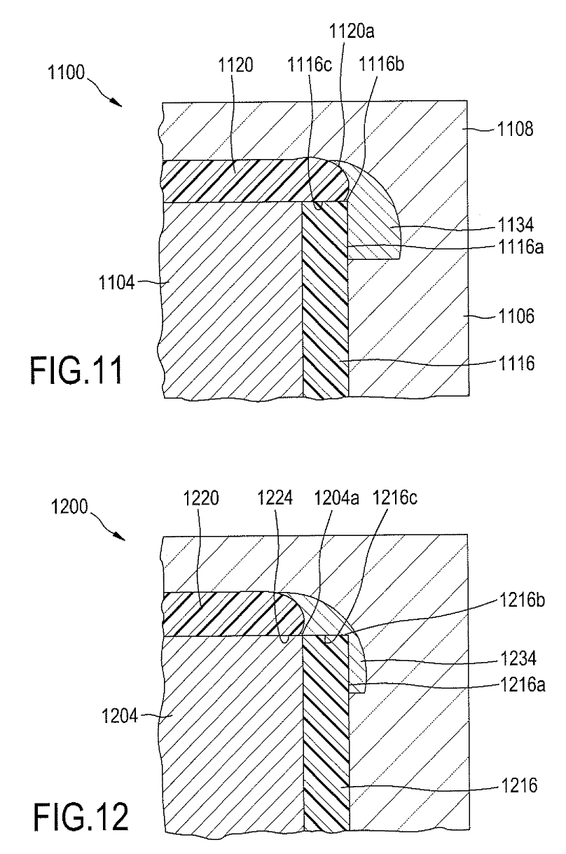

FIG. 11 shows a schematic enlarged cross-sectional view of a portion of an interconnect structure that includes a top lateral section of an interconnect line and an adjacent lateral barrier liner, according to a third embodiment of a metal-interconnect structure.

FIG. 12 shows a schematic enlarged cross-sectional view of a portion of an interconnect structure that includes a top lateral section of an interconnect line and an adjacent lateral barrier liner, according to a fourth embodiment of a metal-interconnect structure.

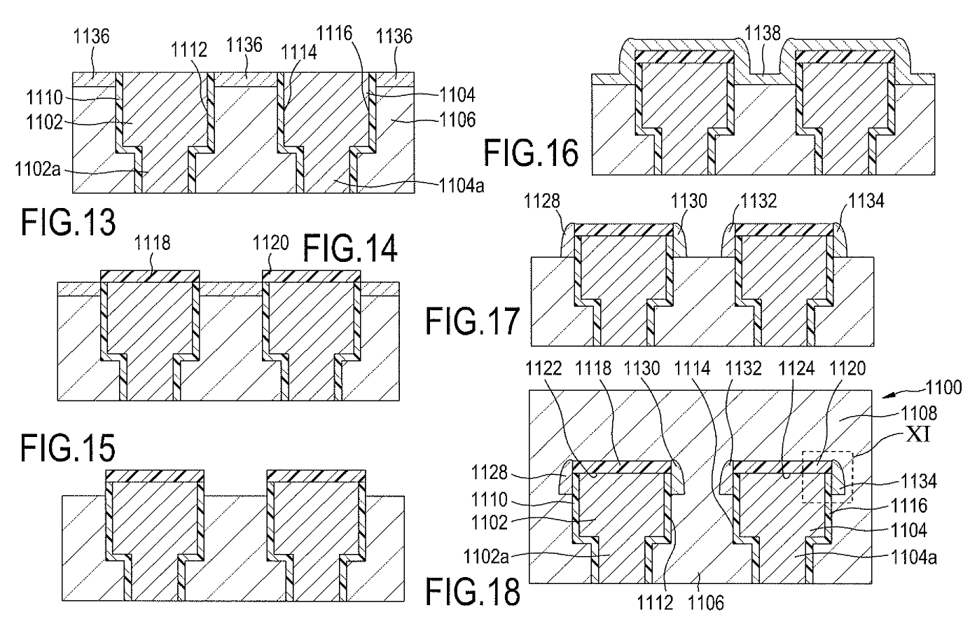

FIGS. 13 to 18 show different steps during the processing of the interconnect structure of FIG. 11 according to an embodiment of the method of the invention.

Reference is now made to FIGS. 3 and 9 together. FIG. 9 shows a schematic cross-sectional view of a portion of an interconnect structure, and FIG. 3 shows an enlarged view corresponding to a section marked III in FIG. 9.

The metal-interconnect structure of FIGS. 3 and 9 forms an embodiment that corresponds to the third alternative configuration of the metal-interconnect structure of the invention described before. FIG. 9 only shows a portion of an interconnect structure 300 of an integrated-circuit device. The present illustration does not include substrate portions of the integrated-circuit device. As is well known in the art, integrated-circuit devices comprise a substrate with integrated-circuit elements like transistors, diodes, resistors, and other well-known integrated-circuit elements. An interconnect structure such as interconnect structure 300 serves to provide interconnects between different integrated-circuit elements so as to allow the communication of electrical signals between the integrated-circuit elements. Since the present invention relates to structural features of a metal-interconnect structure, the following description of preferred embodiments focuses on different embodiments of metal-interconnect structures. However, it is understood that such metal-interconnect structures will always be arranged on a substrate, such as a silicon wafer or on a chip obtained from such a wafer with integrated-circuit elements.

The present description further focuses on structural details of the interconnect structure of the integrated-circuit element of the invention. In order to clearly show such structural details, a high degree of magnification is necessary, not permitting to show of a complete interconnect structure. Typical interconnect structures may comprise seven or more interconnect levels. Therefore, the figures use one or two exemplary interconnect lines to explain a respective embodiment of the invention. The portion of interconnect structure 300, which is illustrated in FIG. 3 is indicated in FIG. 9 as a dashed square outline. For reasons of clarity, the following description will therefore first turn to FIG. 9.

In FIG. 9, a portion of an interconnect structure is shown that contains two interconnect lines 302 and 304, which are separated from each other by surrounding dielectric layers 306 and 308. The dielectric layers are in one embodiment made of SiOC.

As is obvious for a person skilled in the art, the interconnect structure 300, which is illustrated by two exemplary interconnect lines 304 and neighboring structural elements, is characteristic for a dual damascene architecture. The interconnect lines 302 and 304 are made of copper. In order to prevent an outdiffusion of copper in surrounding dielectric regions, and in order to prevent penetration of any material that can corrode copper during or after the fabrication of the interconnect structure, lateral barrier liners are provided abutting the copper interconnect line 302 and 304 on their side faces 310 to 316.

For a person skilled in the art it is obvious that interconnect lines 302 and 304 are formed to provide an electrical contact to further interconnect lines or interconnect segments, which are provided in interconnect structure 300 on a next lower level, by via segments 302a and 304a, respectively. Therefore, no barrier liners are provided on bottom faces 318 and 320 of interconnect lines 302 and 304, respectively, in the present example. It is understood, however, that an interconnect line will be completely separated from the surrounding inter-metal dielectric layer 306 by the barrier liner, where no via segments 302a and 304a are provided to the interconnect lines 302 and 304. The barrier liner thus forms a continuous layer along lateral and bottom faces in such sections without via segments. However, for reasons of clarity, the lateral barrier liners on different faces will be referred to individually with individual reference labels, even though they may actually form parts of a single barrier liner.

The lateral barrier liners are produced by known methods. Suitable materials for lateral barrier liners are TaN, Ta, TiN, to name a few prominent examples. However, further suitable materials are known to the person skilled in the art and can be used as well. Also, combinations of suitable materials can be employed, such as TaN/Ta.

Top faces 322 and 324 of the interconnect lines 302 and 304 are covered by a top barrier liner 326 in the form of a dielectric capping layer. The dielectric capping layer 326 also continues between the interconnect lines. Such dielectric capping layer sections, which are marked with reference numerals 326a and 326b in FIG. 3, are referred to as first top-barrier-liner sections hereinafter and in the claims. A suitable material for the dielectric capping layer 326 is, by way of example, silicon nitride, silicon carbide, or SiCN. The function of the dielectric capping layer 326 corresponds to that of the lateral barrier liners 310 to 316, that is, prevention of outdiffusion of copper from interconnect lines 302 and 304, and prevention of penetration of corroding materials into interconnect lines 302 and 304. The dielectric capping layer serves to correspondingly protect the top face of the metal interconnect line 304.

The interconnect structure 300 includes capping spacers 328, 330, 332, and 334, which are arranged abutting and covering top lateral sections of the lateral barrier liners 310, 312, 314, and 316, respectively. As can be seen in the enlarged views of FIG. 3, the capping spacers, in this case, capping spacer 334, is arranged abutting and covering a top section 316a the lateral outer face 316b of the lateral barrier liner 316 and extends to an outer top edge 316c of the lateral barrier liner 316. The capping spacers are covered on their top faces by the top barrier liner 326.

Note that the first top-barrier-liner sections 326a and 326b, which extend between two laterally neighboring interconnect lines on the same interconnect level, include the second top-barrier-liner section 326a, which is arranged closer to the substrate than a top face 304b of the interconnect line 304.

The capping spacer 334 is laterally arranged between the lateral barrier liner 316 of interconnect line 300 and the second top barrier liner section 326a, and covered by a bending portion 326b of the first top barrier liner section. The bending portion 326b continues the top barrier liner that covers the top face 304a of the interconnect line 304 and, on its other end, abuts the respective second top-barrier-liner section 326a.

The material of the capping spacer preferably has a large dielectric constant. A preferred range of the dielectric constant of the capping spacer 334 is k>7. In particular, it is preferred that the capping spacer 334 has a larger dielectric constant than the dielectric capping layer 326 and the inter-metal dielectric layers 306 and 308. This way, the time-dependent dielectric-breakdown (TDDB) characteristics of the inter-metallic dielectric material as a whole are improved. Suitable capping spacer materials include SiC, SiN, and SiCN.

It is understood that the structural details shown in FIG. 3 are also realized for the capping spacers 328, 330, and 332.

The provision of the capping spacers and the particular arrangement of the capping spacers described above eliminates critical edges, which were present in prior art interconnect structures described with reference to FIGS. 1 and 2. The capping spacers also eliminate the problem of interline leakage and optimize the interline capacitance due to their large dielectric coefficient k. This in turn enables a reduction of the thickness of the dielectric capping layer 326 in order to minimize the interline capacitance without a risk of misalignment of via sections like via sections 302a and 304a. Furthermore, dielectric interfaces in the inter-metal dielectric are minimized, therefore improving the mechanical stability. Of course, the width of the capping spacers 328 to 334 can be monitored in order to secure a proper alignment of the vias.

In the following, the fabrication of the metal interconnect structure of FIGS. 3, and 9 will be described. FIGS. 4 to 9 show different steps during the processing of this interconnect structure according to an embodiment of the method of the invention.

The present description starts at a processing stage, in which the interconnect lines 302 and 304 including respective via segments 302a and 304a have been formed on a particular interconnect level.

The processing is repeated for each interconnect level, with exceptions applying for the lowest interconnect level. Here, for a direct electrical connection between the copper interconnect lines, such as interconnect lines 302 and 304, to integrated-circuits elements it would be harmful to employ copper vias. For an outdiffusion of copper into the integrated-circuit element would, among other effects, create recombination centers for charge carriers in the silicon areas of the integrated-circuit element, thus affecting the operational characteristics of the device. Therefore, tungsten is used for via segments on the lowest interconnect level.

The processing stage shown in FIG. 4 can be reached using a dual damascene process. As is well known in the art, the dual damascene process involves depositing a dielectric layer on a substrate comprising integrated-circuit elements, or the preceding interconnect level. For fabricating interconnect lines in the deposited dielectric layer 306, a hard mask 336 is deposited on the dielectric layer and opened at desired positions of the interconnect lines. Recesses are formed through the hard mask in the dielectric layer for each interconnect line through the openings of the hard mask. The formation of the recesses in a dual damascene technology is a two-step process, which involves a first step, in which the shape of the via is etched into the hard mask and the dielectric layer using a first lithographic step. In a next lithographic step, the via pattern is transferred deeper into the dielectric layer, and at the same time, the recess for the interconnect line is formed. Subsequently, lateral barrier layers 310 to 316 are deposited on the sidewalls of the recesses. Afterwards, the recess formed this way is filled with copper. A step of chemical-mechanical polishing (CMP) follows, in which copper is removed from all areas outside the interconnect lines.

It is this step of CMP, which in prior art devices causes damage to the hard mask 336. The damage includes dangling bonds on the surface of the hard mask, impurities, which are transferred into the hard mask, and other defects such as structural defects like dislocations, cracks etc.

In the processing of the present invention, the hard mask is removed after the CMP step, cf. FIG. 5. As can be seen in FIG. 5, top lateral sections 310a, 312a, 314a, and 316a of the lateral barrier liners 310 to 316 are exposed after the removal of the hard mask.

In a next step, capping spacers are formed. First, a capping-spacer layer 338 is deposited. Suitable materials for the capping-spacer layer 338 are SiC, SiN, and SiCN. The intermediate processing stage after the deposition of the capping-spacer layer 338 is shown in FIG. 6.

The capping-spacer layer 338 is then etched back by a mask-less etching step to form the dielectric capping spacers 328 to 334 and expose the inter-metal dielectric layer 306 in sections arranged between the dielectric capping spacers, cf. FIG. 7. The capping-spacer layer is also removed from the top faces 322 and 324 of the interconnect lines 302 and 304.

Afterwards, the dielectric capping layer 326 is deposited on top of this structure (cf. FIG. 8), followed by the deposition of a second inter-metal dielectric layer 308, cf. FIG. 9.

By achieving an improved operational reliability in particular for interconnect structures in ultra-high scale integration technologies, the described processing provides a significant improvement over prior-art dual damascene processes. It is also applicable in a “single” damascene process.

Next, three further alternative embodiments of an interconnect structure for an integrated circuit device will be described. All three embodiments involve the use of self-aligned top barrier liners instead of a dielectric capping layer.

FIG. 10 shows an embodiment of an interconnect structure 1000 that comprises self-aligned top barrier liners in a magnified view corresponding to that of FIG. 3. Alternative embodiments with self-aligned barriers will be disclosed further below with reference to FIGS. 11 and 12. The interconnect structure of FIG. 10 forms an embodiment of the first alternative configuration of the interconnect structure of the invention.

The section of the interconnect structure 1000 shown in FIG. 10 comprises an interconnect line 1004. The interconnect line 1004 is embedded in a dielectric layer 1006, but confined by a lateral barrier liner 1016. Furthermore, a self-aligned top barrier liner 1020 is arranged on a top face 1024 of interconnect line 1004, respectively. The self-aligned top barrier liner 1020 can be made by Tungsten CVD, by electroless Cobalt materials, or other suitable metal barrier materials, which are known in the art. As an alternative, the self-aligned top barrier liner 1020 can be made of a metal, which is suitable for preventing a diffusion of copper out off the interconnect lines, and to prevent a leakage of materials, which are suitable for corroding the copper interconnect lines. Suitable materials are for instance TiN, TaN, deposited by atomic layer deposition (ALD) or by any other suitable technique, as well as other materials known in the art.

Depending on the process selectivity, the self-aligned deposition process will include the top face of the lateral barrier liner 1016, shown by way of example with reference label 1016c, or it will not cover these top faces. The latter situation is given in the present embodiment, where the self-aligned top barrier liner 1020 only covers the top face 1024 of the interconnect line 1004, while a top face 1016c of lateral barrier liner 1016 is not covered by the top barrier liner 1020.

A capping spacer 1034 is arranged abutting and covering an outer top edge 1004a of the interconnect line 1004 and outer bottom edge of the top barrier layer. The capping spacer 1034 extends along a top lateral section 1016a of the lateral barrier liner 1016.

Due to the nature of the self-aligned deposition process used for the fabrication of the top barrier liner 1020, the outer top edge 1004a of the interconnect line 1004 is not covered by the top barrier liner. This critical edge would in a prior-art device affect the reliability of the interconnect structure 1000 due to an electrical-field concentration. This critical edge is avoided in the interconnect structure 1000 by providing the capping spacer 1034. The material of the capping spacer for the present embodiment can be selected from the same dielectric materials and from metallic materials, which have been mentioned in the context of the previous embodiment, described with reference to FIGS. 3 to 9.

FIG. 11 and FIG. 18 show an alternative embodiment of an interconnect structure that has self-aligned top barrier liners. The relation between FIGS. 11 and 18 resembles that of FIGS. 3 and 9. FIG. 11 shows an enlarged view of a section marked XI and indicated by a dashed square in FIG. 18. As mentioned before in the context of FIGS. 3 and 9, only an exemplary portion of an interconnect structure 1100 is shown here to illustrate the present embodiment of the invention.

Referring first to FIG. 18, the section of interconnect structure 1100 that is shown in this Fig. comprises two interconnect lines 1102 and 1104 having respective via sections 1102a and 1104a for connecting to interconnect lines on a next lower interconnect level. The interconnect lines are embedded in dielectric layers 1106 and 1108, but confined by lateral barrier liners 1110 to 1116. Furthermore, self-aligned top barrier liners 1118 and 1120 are arranged on top faces 1122 and 1124 of interconnect lines 1102 and 1104, respectively. The self-aligned barrier liners can be made by Tungsten CVD or electroless Cobalt materials, or other suitable metal barrier materials, which are known in the art. As an alternative, the self-aligned top barrier liners 1118 and 1120 can be made of a metal, which is suitable for preventing a diffusion of copper out off the interconnect lines, and to prevent a leakage of materials, which are suitable for corroding the copper interconnect lines. Suitable materials are for instance TiN, TaN, deposited by atomic layer deposition (ALD) or by any other suitable technique, as well as other materials known in the art.

Under the process selectivity given in the fabrication process for the present embodiment for this particular embodiment, the self-aligned deposition process includes the top faces of lateral barrier liners, shown by way of example with reference label 1116c. As clearly visible in the detailed view of FIG. 11, the top barrier liner 1120 thus extends to an outer edge 1116b of the lateral barrier liner 1116 on the right lateral side of interconnect line 1104. The same holds for the other outer edge on the left lateral side, which is not shown in FIG. 11, but in less detail in FIG. 18. The present embodiment thus corresponds to the second alternative configuration of the interconnect structure of the invention.

Capping spacers 1128, 1130, 1132, and 1134 are arranged abutting and covering a top section of a respective lateral outer face of the lateral barrier liners, such as lateral barrier liner 1116, and, in a direction from the substrate to the top barrier liner 1120, extend beyond the outer top edge 1116c of the lateral barrier liner 1120 along a lateral outer face 1120a of the top barrier liner 1120. As can be seen in more detail in the enlarged view of FIG. 11, the capping spacer 1134 extends along a top lateral section 1116a and covers also the outer top edge 1116b of the lateral barrier liner 1116. While FIG. 18 shows the lateral edges of the top barrier liners 1118 and 1120 in a simplified schematic view, the enlarged view of FIG. 11 reveals the geometrical structure of the top barrier liner 1120 on top of interconnect line 1104 in greater detail.

As mentioned before, due to the nature of the self-aligned deposition process used for the fabrication of the top barrier liner 1120, the outer top edge 1116b of the lateral barrier liner 1116 is not covered by the top barrier liner 1120. This critical edge would in a prior-art device affect the reliability of the interconnect structure 1100 due to an electrical-field concentration, in case a metallic lateral barrier liner is used. This critical edge is avoided in the interconnect structure 1100 by providing the capping spacer 1134. The material of the capping spacer for the present embodiment can be selected from the same dielectric materials and from metallic materials, which have been mentioned in the context of the previous embodiment, described with reference to FIGS. 3 to 9.

Reference is now made to FIG. 12, which shows an enlarged view of a further alternative embodiment of the interconnect structure 1200 of the invention. The view of FIG. 12 corresponds to that of FIGS. 11 and 10. The description concentrates on difference in the structure in comparison to FIGS. 11 and 10. In the embodiment of FIG. 12, capping spacers such as capping spacer 1234 cover the complete top face of the respective lateral barrier liners, such as shown for the example of a top face 1216c of lateral barrier liner 1216, which corresponds lateral barrier liner 1116 or 1112 in FIG. 18. Interconnect structure 1200, like that of FIG. 10, thus forms an embodiment of the first alternative configuration of the metal interconnect structure of the invention.

However, in contrast to the embodiment of FIG. 10, the capping spacer 1234 not only seals a critical edge 1204a on the top corner of the interconnect line 1204, which is not covered by the top barrier liner 1220. The capping spacer is also arranged abutting and covering an outer top edge 1216b of the interconnect line 1204 and a top section 1216a of the lateral outer face of the lateral barrier liner 1216.

Next, the fabrication of the interconnect structure 1100 of FIGS. 11 and 18 will be described with reference to FIGS. 13 to 18.

The starting point of the fabrication of interconnect structure 1100 is identical to that for the fabrication of interconnect structure 300 of FIGS. 3 and 10. Therefore, FIG. 13, which is identical to FIG. 5, will not be described in detail. Reference numerals used in FIG. 5 are transferred to those given in FIG. 13 by replacing the leading digit “3” with “11”. Therefore, corresponding reference numerals denote identical structural elements in FIGS. 5 and 13.

In contrast to the processing embodiment of FIGS. 5 to 10, the top barrier liners 1118 and 1120 are deposited self-aligned on the interconnect lines 1102 and 1104, and on the top faces of lateral barrier liners 1110 to 1116. As mentioned before, the lateral extension of the top barrier liners 1118 and 1120 depends on the selected materials for the top barrier liners and for the lateral barrier liners. Therefore, the present description is also representative for the fabrication of the interconnect structure 1200 of FIG. 12, which follows the same processing sequence, except for using different materials in the deposition of self-aligned top barrier liners.

For the deposition of self-aligned barrier liners 1118 and 1120, it is important to choose a material that does not form a layer to the hard mask sections 1136. A typical hard-mask material is USG. However, other suitable hard-mask materials may be chosen depending on the desired material of the top barrier liners 1118 and 1120.

In a next step, the result of which is shown in FIG. 15, the hard mask 1136 is removed from the interconnect structure by etching. After that, as can be seen in FIG. 16, a capping-spacer layer 1138 is deposited. The capping-spacer layer 1138 is made of the desired material of the capping spacers (cf. FIG. 16). In a next step, the capping spacer layer 1138 is etched back to form the capping spacers 1128 to 1134. After that, dielectric layer 1108 is deposited to form the interconnect structure shown in FIG. 18.

The previous description of embodiments of the integrated-circuit device of the invention and of preferred methods for fabricating such integrated-circuit devices shows that the concept of providing capping spacers abutting and covering critical edges on the outer top corner of lateral barrier liners or, in a specific self-aligned top barrier liner configuration, also at the inner top edge of the lateral barrier liner improve the operational reliability of the interconnect structure. The capping spacers avoid negative effects of a concentration of an electric field at the critical edges. Furthermore, the interconnect structures avoid the disadvantages of a damaged residual hard mask by completely or partially removing hard mask sections after chemical mechanical polishing. This way, interline leakage currents are reduced and the interline capacitance is reduced. Furthermore, the dielectric interface between residual hard-mask sections and other inter-metal dielectrics is eliminated, thus improving the mechanical stability of the interconnect structure.

Furthermore, the capping spacers improve the sealing of the interconnect lines and therefore avoid copper corrosion due to a penetration of chemical species such as HF into the interconnect lines. Furthermore, the capping spacers also improve the prevention of an outdiffusion of copper into the inter-metal dielectric, which thus also helps to avoid an interline current leakage path that is detrimental for operation of an integrated-circuit device.

The metal-interconnect structures of the above embodiments solve several problems of operational reliability in damascene interconnect structures, due to corner effects and structural defects present at top edges of interconnect lines fabricated according to prior-art processing technologies.

While the invention is particularly useful for integrated-circuit devices that implement present-day and future ULSI technologies at the 90 nm technology node and below, it is obvious, that the invention can be applied in any damascene or dual damascene interconnect structure, in which the metal of the interconnect lines needs to be confined by barrier liners in order to protect the interconnect lines and the surrounding inter-metal dielectric from a mutual contact.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

Furthermore, the invention may also be embodied with less components than provided in the embodiments described here, wherein one component carries out multiple functions. Just as well may the invention be embodied using more elements than depicted in FIG. 1, wherein functions carried out by one component in the embodiment provided are distributed over multiple components.

A person skilled in the art will readily appreciate that various parameters disclosed in the description may be modified and that various embodiments disclosed and/or claimed may be combined without departing from the scope of the invention.

In the following claims, reference numbers shall not be construed as a limitation of the scope of the claims.

1. A metal-interconnect structure on a substrate, comprising a plurality of metal interconnect lines on one or more interconnect levels, the metal interconnect lines comprising copper and being separated laterally from an inter-metal dielectric by a respective lateral barrier liner, and being separated on their top face from the inter-metal dielectric by a top barrier liner, the lateral and top barrier liners each forming a barrier against a penetration of copper out off a respective metal interconnect line and against a penetration of a material suitable for corroding copper into a respective metal interconnect line, wherein;
in a first alternative, the top barrier liner of a respective interconnect line extends only on the metal of the interconnect line, and capping spacers are arranged abutting and covering respective outer top edges of the interconnect line and outer bottom edges of the top barrier liner, or,
in a second alternative, the top barrier liner of a respective interconnect line extends from an outer edge of a lateral barrier liner on one lateral side of a respective interconnect line to an outer edge of a lateral barrier liner on an opposite lateral side of the respective interconnect line, and capping spacers are arranged abutting and covering a top section of a respective lateral outer face of the lateral barrier liner, and extend beyond an outer top edge of the lateral barrier liner along a respective lateral outer face of the respective top barrier liner, or,
in a third alternative, the top barrier liner of an interconnect line laterally continues between neighboring interconnect lines, and capping spacers are arranged abutting and covering a top section of a respective lateral outer face of the lateral barrier liner and extending to an outer top edge of the lateral barrier liner, the capping spacers being covered on their top faces by the top barrier liner.

2. The metal-interconnect structure of claim 1, wherein the capping spacers either comprise or consist of an electrically insulating material.

3. The metal-interconnect structure of claim 1, wherein the capping spacers either comprise or consist of a metallic material that is suitable for forming a barrier against a penetration of copper out off a respective interconnect line and against a penetration of a material suitable for corroding copper into a respective interconnect line.

4. The metal-interconnect structure of claim 1, wherein the capping spacers comprise a first layer of an electrically insulating material and a second layer of a metallic material.

5. The metal-interconnect structure of claim 1, wherein the capping spacers comprise a material that has a higher dielectric coefficient than the inter-metal dielectric.

6. The metal-interconnect structure of claim 1, wherein the capping spacers comprise silicon nitride, silicon carbide, or a mixture of silicon carbide and silicon nitride.

7. The metal-interconnect structure of the third alternative of claim 1, wherein first top-barrier-liner sections, which extend between two laterally neighboring interconnect lines on the same interconnect level, contain second top-barrier-liner sections, which are arranged closer to the substrate than the top faces of the interconnect lines, and wherein a respective capping spacer is laterally arranged between the lateral barrier liner of a respective interconnect line and a respective second top barrier liner section, and covered by a bending portion of the first top barrier liner section, which extends between the top face of the respective interconnect line and the respective second top-barrier-liner section.

8. The metal-interconnect structure of the first or second alternative of claim 1, wherein an outer face of the capping spacers is arranged abutting the inter-metal dielectric.

9. The metal-interconnect structure of the first alternative of claim 1, wherein a bottom face of a respective capping spacer laterally extends either only on an abutting top face of the respective lateral barrier liner (1016) or on an abutting top face of the respective lateral barrier liner and into the inter-metal dielectric.

10. An integrated-circuit device with a substrate comprising a plurality of integrated-circuit elements, and with a metal-interconnect structure according to claim 1 on the substrate.

11. A method for fabricating a metal-interconnect structure on a substrate, comprising the steps of:
providing a substrate comprising a plurality of integrated-circuit elements; depositing a dielectric layer; fabricating a plurality of interconnect lines in the dielectric layer; wherein the step of fabricating the plurality of interconnect lines comprises:
depositing a hard mask on the dielectric layer and opening the hard mask at desired positions of the interconnect lines;
forming recesses in the dielectric layer for the interconnect lines through the openings of the hard mask;
depositing a lateral barrier liner in the recesses;
depositing a metal comprising copper;
removing the deposited metal from outside the recesses;
depositing a top barrier liner on each interconnect line; wherein
in a first alternative, the top barrier liner of a respective interconnect line is deposited only on the metal of the interconnect line, and the capping spacers are arranged abutting and covering respective outer top edges of the interconnect line and outer bottom edges of the top barrier layer, or,
in a second alternative, the top barrier liner of an interconnect line is deposited with a lateral extension from an outer edge of a lateral barrier liner on one lateral side of a respective interconnect line to an outer edge of a lateral barrier liner on an opposite lateral side of the respective interconnect line, and capping spacers are formed abutting and covering a top section of a respective lateral outer face of the lateral barrier liner, and extending beyond the outer top edge of the lateral barrier liner along a respective lateral outer face of the respective top barrier liner, or,
in a third alternative, before the step of depositing the top barrier liner, capping spacers are formed abutting and covering a top section of a respective lateral outer face of the lateral barrier liner and extending to an outer top edge of the lateral barrier liner, and wherein the top barrier liner of an interconnect line is deposited laterally continuing between neighboring interconnect lines, thus covering the top faces of the capping spacers with the top barrier liner.

12. The method of claim 11, comprising a step of partially or totally removing the hard mask, which step is performed in the first and second alternatives before the step of depositing the top barrier liner, and in the third alternative before the step of depositing the capping spacers.

13. The method of claim 12, wherein the hard mask is removed in a mask-less etching step.

14. The method of claim 11, wherein the step of fabricating capping spacer comprises a step of depositing a capping-spacer layer and an etching step applied to the capping-spacer layer so as to form the capping spacers.

15. The method of the first and second alternatives of claim 11, wherein the top barrier liner is deposited in a self-aligned manner.

16. A method for fabricating an integrated-circuit device, comprising a step of fabricating a metal-interconnect structure on a substrate performed according to the method of claim 11.
